(19) United States
(12) Patent Application Publication
(10) Pub. No.: US 2026/0330113 A1
(43) Pub. Date: Oct. 22, 2026

(54) Method and System for Agent-Based Semantic Characterization and Self-Supervised Validation of Electronic Components Using Simulation and Expert Feedback

(71) Applicant: NeuroCAD Inc., Atlanta, GA (US)

(72) Inventor: Matthew Berggren, Marietta, GA (US)

(21) Appl. No.: 19/186,307

(22) Filed: Apr. 22, 2025

Related U.S. Application Data
(60) Provisional application No. 63/792,155, filed on Apr. 21, 2025.

(51) Int. Cl. G06F 30/3308; G06F 30/323

(52) U.S. Cl. CPC G06F 30/3308; G06F 30/323

(57) ABSTRACT

A system and method for semantic characterization and validation of electronic components using a Mixture-of-Experts (MoE) agent architecture. The system comprises: (1) a content orchestration agent responsible for extraction and normalization of device datasheet information, and (2) a simulation-generation agent which produces subcircuit models using a structured grammar and validates them via self-supervised SPICE simulations. The agents collaborate iteratively to construct scenarios reflective of real-world operating conditions, bridging the gap between idealized datasheet curves and actual component behavior. Simulation results are analyzed using clustering algorithms to form a performance taxonomy, enabling deterministic classification, similarity analysis, and circuit design recommendations.

### RELATED SUBMISSIONS

This application and its contents are pursuant to U.S. Patent Application 63/792,155 filed Apr. 21, 2025 and is submitted in support of the utility outlined in both the original application referenced and the claims made herein.

### 2. BRIEF DESCRIPTION OF THE DRAWINGS

FIG. 1. is a flow diagram depicting Extraction of Piecewise Linearized (PWL) SPICE simulation model.

FIG. 2 is a flow diagram depicting Introduction of Simulation Agent for SPICE simulation and model characterization.

FIG. 3 is a flow diagram depicting Construction of SPICE network listing (netlist) and simulation execution.

FIG. 4 is a flow diagram depicting Parametric search classification employing simulation as source.

FIG. 5 is a flow diagram depicting Feedback and Model Enrichment Utilizing Simulation Standard Delay Format (.sdf)

### 3. BACKGROUND

Conventional simulation and characterization methods for electronic components rely heavily on manufacturer-supplied SPICE models or tabular metadata. However, these models often reflect idealized performance or incomplete behavioral boundaries. Additionally, the lack of semantic connection between observed performance and structured function prevents AI agents from accurately selecting or substituting parts in real-world circuit design.

This invention addresses that gap by enabling expert agents to interpret datasheets, simulate behavior, and derive functionally aware taxonomies from observed electrical performance—not metadata.

### 4. SUMMARY OF THE INVENTION

This system introduces a two-agent architecture designed for AI-driven extraction, interpretation, and validation of electronic component behavior:

### 4.1 Orchestration Agent

Extracts plots, tables, and textual context from PDFs or structured documents
Normalizes content into a symbolic grammar (e.g., Neurocad Script)
Manages dataflow and inter-agent dialogue using semantic tokens [Reference Original, Application ID: 63/792,155 Received: 04/21/2025]

### 4.2. Simulation Agent

Interprets symbolic circuit fragments and constructs SPICE models
Iteratively generates test conditions to mirror or extend datasheet curves
Performs simulation and interprets results for self-supervised correction

### 4.3 Grammar as a Protocol

Agents communicate using a domain-specific language that defines parametric designs, sweeps, and topologies
Enables agents to reason abstractly about circuit configuration without resorting to natural language

### 4.4. Clustering and Classification

Simulation output is clustered using methods such as Agglomerative Hierarchical Clustering, DBSCAN, or KMeans Clustering
Results are used to form deterministic similarity groupings, enabling cross-reference and substitution between parts

### 4.5. Application-Level Benefits

Part selection and substitution driven by performance, not part number
Improved SPICE validation over static models
Discovery of new component applications via semantic clustering

### 5. SYSTEM ARCHITECTURE

The system comprises a plurality of AI agents, described as a Mixture of Experts each specialized in a task-restricted domain, coordinated through a shared orchestration grammar.

### 5.a Agent Roles and Language Design

Each agent operates using a task-specific mini-language tailored to its function (e.g., SPICE circuit construction, curve modeling, clustering).
A wider orchestration grammar governs inter-agent communication, enabling intent transfer and task queuing.
Agents are interoperable and modular, allowing substitution, stacking, or fine-tuning without retraining the system as a whole.

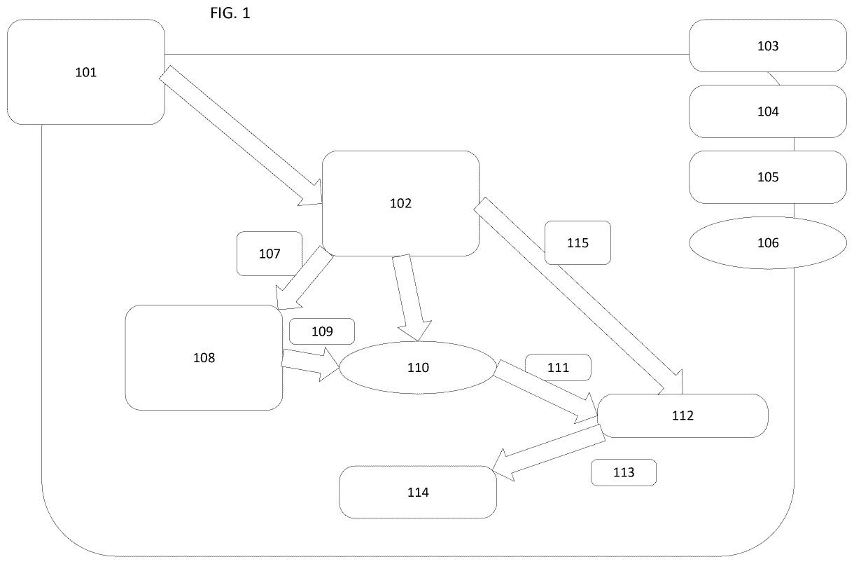

### 5.b Orchestration Agent: [FIG. 1]

Accepts external input via API, user submission, or direct database query.
Parses the input and invokes the extraction pipeline described in the parent patent.
Coordinates the conversion of source data into usable simulation models.
Generates prompts in orchestration grammar, directing the Simulation Agent's activity.

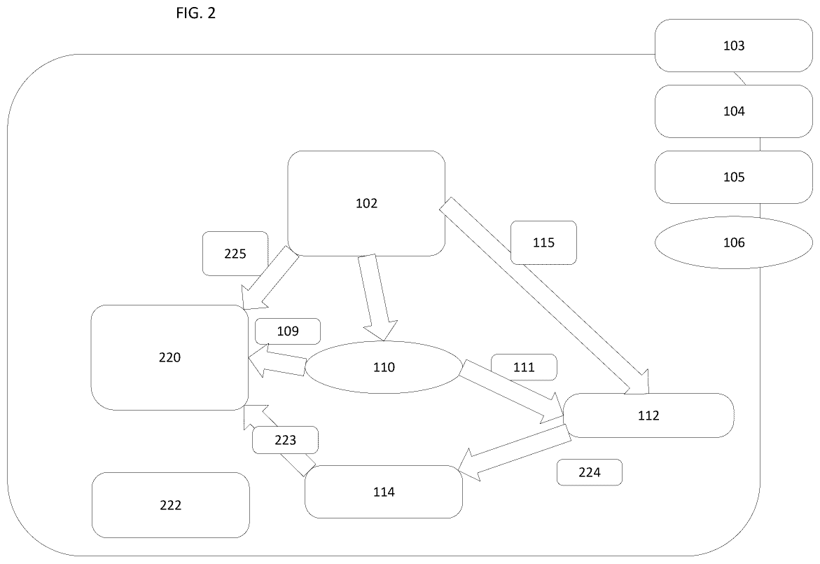

### 5.c Simulation Agent: [FIG. 2, 3]

Receives extracted SPICE models, datasheet metadata, and classified curve information.
Constructs subcircuit representations using a custom grammar capable of expressing:
   Symbolic elements (e.g., MOSFET, RLC blocks)
   Topologies (mesh, star, cascaded)
   Functional constraints (biasing, clamping, feedback)
Generates a schematic representation including node/mesh networks and PWL input sources.
Assembles a netlist and prepares the system for simulation.

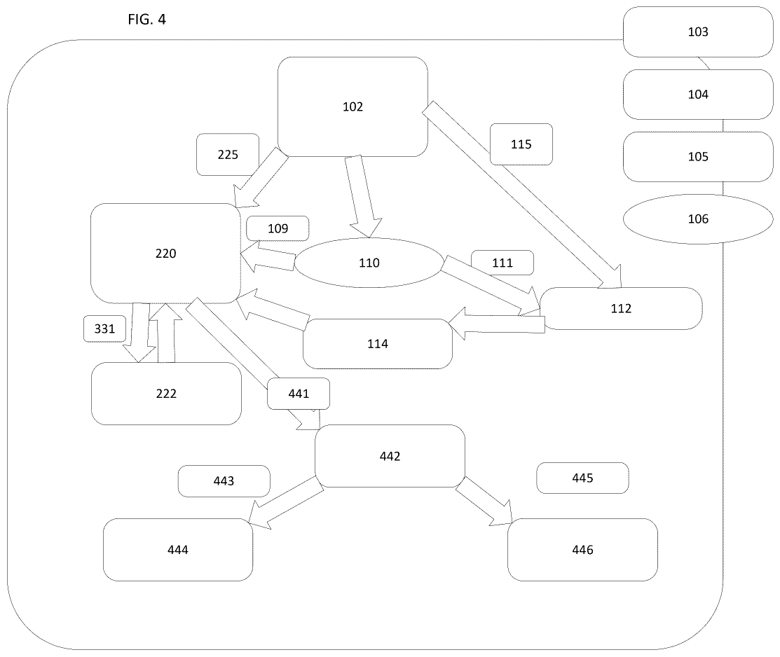

### 5.d Circuit Execution Pipeline: [FIG. 4]

The outcome of the Simulation Agent's process includes a full schematic model, a SPICE netlist, and annotated metadata.
This is returned via API to the Orchestration Agent, which initializes simulation infrastructure, submits models and netlists, triggers the simulation run, and routes the resulting waveform output back to the Simulation Agent for analysis.

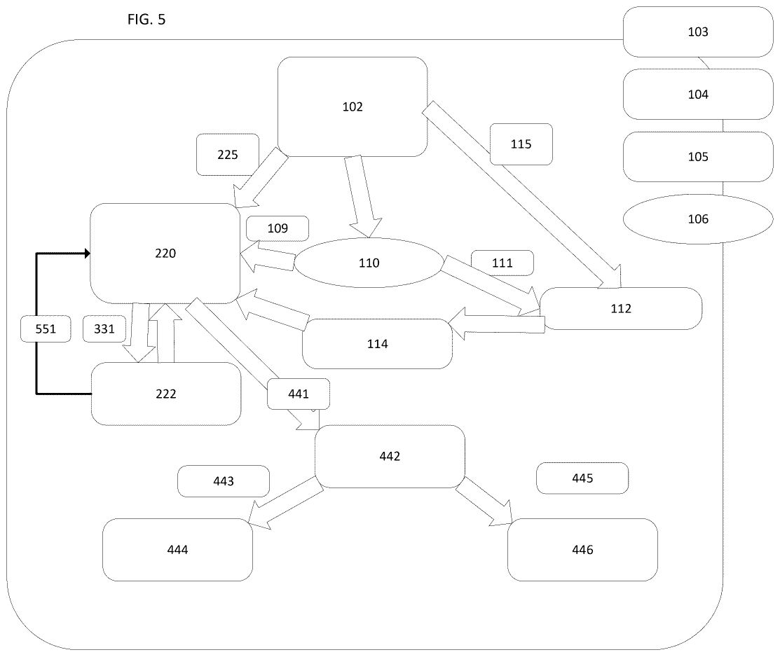

### 5.e Feedback and Model Enrichment: [FIG. 5]

Simulation outputs are used to train embedding models, cluster similar devices, update taxonomy, and propose substitutions based on performance equivalence rather than manufacturer metadata.

### Elements in the Figures

FIG. 1. is a flow diagram depicting Extraction of Piecewise Linearized (PWL) SPICE simulation model. Elements in FIG. 1: 101 PDF Datasheet; 102 Switch Agent (Task Router); 103 Agent; 104 CIP Component; 105 Processing Module; 106 Protocol; 107 Extraction Request; 108 CIP-1 Curve Extraction; 109 NURBS Data; 110 Grammar; 111 Generated Script; 112 Model Generation Service; 113 Model Results; 114 SPICE Model Library; 115 Task Assignment.

FIG. 2 is a flow diagram depicting Introduction of Simulation Agent for SPICE simulation and model characterization. Elements in FIG. 2: 102 Switch Agent (Task Router); 103 Agent; 104 CIP Component; 105 Processing Module; 106 Protocol; 107 Extraction Request; 109 NURBS Data; 110 Grammar; 111 Generated Script; 112 Model Generation Service; 113 Model Results; 114 SPICE Model Library; 115 Task Assignment; 220 Simulation Agent (Model Builder); 222 Simulation Kernel; 223 SPICE Model; 224 SPICE Model; 225 Task Assignment.

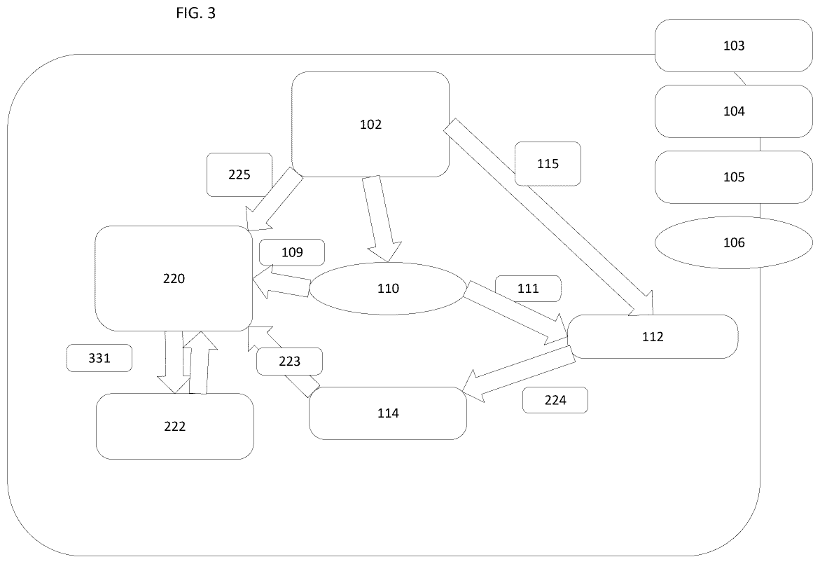

FIG. 3 is a flow diagram depicting Construction of SPICE network listing (netlist) and simulation execution. Elements in FIG. 3: 102 Switch Agent (Task Router); 103 Agent; 104 CIP Component; 105 Processing Module; 106 Protocol; 107 Extraction Request; 109 NURBS Data; 110 Grammar; 111 Generated Script; 112 Model Generation Service; 113 Model Results; 114 SPICE Model Library; 115 Task Assignment; 220 Simulation Agent (Model Builder); 222 Simulation Kernel; 223 SPICE Model; 224 SPICE Model; 225 Task Assignment; 331 SPICE Net List.

FIG. 4 is a flow diagram depicting Parametric search classification employing simulation as source. Elements in FIG. 4: 102 Switch Agent (Task Router); 103 Agent; 104 CIP Component; 105 Processing Module; 106 Protocol; 107 Extraction Request; 109 NURBS Data; 110 Grammar; 111 Generated Script; 112 Model Generation Service; 113 Model Results; 114 SPICE Model Library; 115 Task Assignment; 220 Simulation Agent (Model Builder); 222 Simulation Kernel; 223 SPICE Model; 224 SPICE Model; 225 Task Assignment; 331 SPICE Net List; 441 Performance Characteristic Parameters; 442 Clustering Module (Taxonomy Builder); 443 Validated Models; 444 SPICE Model Library; 445 Classification; 446 Component Database.

FIG. 5 is a flow diagram depicting Feedback and Model Enrichment Utilizing Simulation Standard Delay Format (.sdf). Elements in FIG. 5: 102 Switch Agent (Task Router); 103 Agent; 104 CIP Component; 105 Processing Module; 106 Protocol; 107 Extraction Request; 109 NURBS Data; 110 Grammar; 111 Generated Script; 112 Model Generation Service; 113 Model Results; 114 SPICE Model Library; 115 Task Assignment; 220 Simulation Agent (Model Builder); 222 Simulation Kernel; 223 SPICE Model; 224 SPICE Model; 225 Task Assignment; 331 SPICE Net List; 441 Performance Characteristic Parameters; 442 Clustering Module (Taxonomy Builder); 443 Validated Models; 444 SPICE Model Library; 445 Classification; 446 Component Database; 551 Performance Characteristics Standard Delay Format (.sdf).

1. A method for generating a circuit simulator model of an electronic component from one or more electronic component datasheets, the method comprising:
receiving, by one or more circuit generation AI agents, the one or more electronic component datasheets and a request to generate the circuit simulator model;
extracting, by the one or more circuit generation AI agents, information from the one or more electronic component datasheets;
transforming, by the one or more circuit generation AI agents, the information into a structured symbolic grammar representation of the information;
generating, by the one or more circuit generation AI agents using the structured symbolic grammar representation of the information, a subcircuit representation of the electronic component;
creating, by the one or more circuit generation AI agents using the structured symbolic grammar representation of the information, a circuit simulator netlist;
executing, by the one or more circuit generation AI agents using the subcircuit representation of the electronic component and the circuit simulator netlist, a circuit simulation to create a simulated performance curve;
verifying, by the one or more circuit generation AI agents using the simulated performance curve, that the subcircuit representation of the electronic component and the circuit simulator netlist accurately represent the information from the one or more electronic component datasheets; and
returning, by the one or more circuit generation AI agents, the circuit simulator model comprising the subcircuit representation of the electronic component and the circuit simulator netlist.

2. The method of claim 1, further comprising:
receiving a request to include the electronic component in a printed circuit board circuit design; and
causing the manufacture of a printed circuit board based on the printed circuit board circuit design.

3. The method of claim 1, further comprising clustering, by the one or more circuit generation AI agents, simulation outputs to form deterministic similarity groupings, wherein the similarity groupings enable cross-referencing and substitution between different electronic components.

4. The method of claim 1, further comprising iteratively refining, by the one or more circuit generation AI agents, symbolic models using simulation error provided by a feedback loop and self-supervised learning.

5. The method of claim 1, wherein the subcircuit representation includes node and mesh networks and PWL input sources.

6. The method of claim 1, wherein the structured symbolic grammar is capable of expressing symbolic elements, topologies, and functional constraints of the electronic component.

7. The method of claim 1, wherein extracting the information from the one or more electronic component datasheets further comprises:
extracting, by the one or more circuit generation AI agents, performance curve image data;
applying, by the one or more circuit generation AI agents, a curve fitting algorithm to the performance curve image data;
recognizing, by the one or more circuit generation AI agents, axis labels of the performance curve image data; and
interpolating, by the one or more circuit generation AI agents, data points on the performance curve.

8. A system for generating a circuit simulator model of an electronic component from one or more electronic component datasheets, the system comprising:
one or more processors; and
one or more memories storing instructions that, when executed by the one or more processors in response to a request to generate the circuit simulation model, cause one or more circuit generation AI agents to perform operations including:
extracting information from the one or more electronic component datasheets;
transforming the information into a structured symbolic grammar representation of the information;
generating, using the structured symbolic grammar representation of the information, a subcircuit representation of the electronic component;
creating, using the structured symbolic grammar representation of the information, a circuit simulator netlist;
executing, using the subcircuit representation of the electronic component and the circuit simulator netlist, a circuit simulation to create a simulated performance curve;
verifying, using the simulated performance curve, that the subcircuit representation of the electronic component and the circuit simulator netlist accurately represent the information from the one or more electronic component datasheets; and
returning the circuit simulator model comprising the subcircuit representation of the electronic component and the circuit simulator netlist.

9. The system of claim 8, wherein the instructions, when executed by the one or more processors, further cause the system to perform operations including:
receiving a request to include the electronic component in a printed circuit board circuit design; and
causing the manufacture of a printed circuit board based on the printed circuit board circuit design.

10. The system of claim 8, wherein the instructions, when executed by the one or more processors, further cause the one or more circuit generation AI agents to perform operations including clustering simulation outputs to form deterministic similarity groupings, wherein the similarity groupings enable cross-referencing and substitution between different electronic components.

11. The system of claim 8, wherein the instructions, when executed by the one or more processors, further cause the one or more circuit generation AI agents to perform operations including iteratively refining symbolic models using simulation error provided by a feedback loop and self-supervised learning.

12. The system of claim 8, wherein the subcircuit representation includes node and mesh networks and PWL input sources.

13. The system of claim 8, wherein the structured symbolic grammar is capable of expressing symbolic elements, topologies, and functional constraints of the electronic component.

14. The system of claim 8, wherein extracting information from the one or more electronic component datasheets further comprises:
extracting performance curve image data;
applying a curve fitting algorithm to the performance curve image data;
recognizing axis labels of the performance curve image data; and
interpolating data points on the performance curve.

15. A method comprising:
receiving, by one or more circuit generation AI agents, a request to generate a circuit simulator model of an electronic component, the request including one or more electronic component datasheets;
extracting, by the one or more circuit generation AI agents, information from the one or more electronic component datasheets;
generating, by the one or more circuit generation AI agents, a subcircuit representation and a circuit simulator model of the electronic component using a structured symbolic grammar representation of information extracted from the one or more electronic component datasheets;
executing, by the one or more circuit generation AI agents using the subcircuit representation of the electronic component and the circuit simulator model, a circuit simulation to create a simulated performance curve;
verifying, by the one or more circuit generation AI agents using the simulated performance curve, that the subcircuit representation of the electronic component and the circuit simulator model accurately represent the information from the one or more electronic component datasheets; and
returning, by the one or more circuit generation AI agents, the circuit simulator model and the subcircuit representation of the electronic component.

16. The method of claim 15, further comprising:
receiving a request to include the electronic component in a printed circuit board circuit design; and
causing the manufacture of a printed circuit board based on the printed circuit board circuit design.

17. The method of claim 15, further comprising clustering, by the one or more circuit generation AI agents, simulation outputs to form deterministic similarity groupings, wherein the similarity groupings enable cross-referencing and substitution between different electronic components.

18. The method of claim 15, further comprising iteratively refining, by the one or more circuit generation AI agents, symbolic models using simulation error provided by a feedback loop and self-supervised learning.

19. The method of claim 15, wherein the structured symbolic grammar is capable of expressing symbolic elements, topologies, and functional constraints of the electronic component.

20. The method of claim 15, wherein extracting information from the one or more electronic component datasheets further comprises:
extracting, by the one or more circuit generation AI agents, performance curve image data;
applying, by the one or more circuit generation AI agents, a curve fitting algorithm to the performance curve image data;
recognizing, by the one or more circuit generation AI agents, axis labels of the performance curve image data; and
interpolating, by the one or more circuit generation AI agents, data points on the performance curve.
